(19) United States
(12) Patent Application Publication
(10) Pub. No.: US 2014/0070179 A1
(43) Pub. Date: Mar. 13, 2014

(54) ORGANIC LIGHT EMITTING DISPLAY DEVICE HAVING IMPROVED AUXILIARY LIGHT EMITTING LAYER STRUCTURE AND MANUFACTURING METHOD THEREOF

(71) Applicant: SAMSUNG DISPLAY CO., LTD., Yongin-Si (KR)

(72) Inventor: Jae-Hoon Kim, Cheonan-si (KR)

(73) Assignee: SAMSUNG DISPLAY CO., LTD., Yongin-Si (KR)

(21) Appl. No.: 13/802,466

(22) Filed: Mar. 13, 2013

(30) Foreign Application Priority Data
Sep. 10, 2012 (KR) 10-2012-0099693

(51) Int. Cl. H01L 27/32; H01L 51/56

(52) U.S. Cl. CPC H01L 27/32; H01L 51/56
USPC 257/40; 438/34

(57) ABSTRACT

An organic light emitting display device includes: a substrate; a first electrode on the substrate; an auxiliary light emitting layer on the first electrode and having a pattern including a plurality of sub-patterns spaced apart from each other; a light emitting layer on the auxiliary light emitting layer; and a second electrode on the light emitting layer.

### CROSS-REFERENCE TO RELATED APPLICATIONS

This application claims priority to and the benefit of Korean Patent Application No. 10-2012-0099693, filed on Sep. 10, 2012, with the Korean Intellectual Property Office, the entire content of which is incorporated herein by reference.

### FIELD

Embodiments of the present invention relate to an organic light emitting display device and a manufacturing method thereof.

### BACKGROUND

An organic light emitting display device is a self-emission display device which has an organic light emitting diode that emits light to display an image. Since the organic light emitting display does not require a separate light source unlike a liquid crystal display, it is possible to relatively reduce thickness and weight thereof and there are advantages of low power consumption, high luminance, and a rapid response speed.

In general, an organic light emitting display device may include a hole injection electrode, a light emitting layer, and an electron injection electrode. In the organic light emitting display device, a hole supplied from the hole injection electrode and an electron supplied from the electron injection electrode are coupled with each other in the light emitting layer to form an exciton, and light is generated by energy generated when the exciton falls in a ground state.

In an organic light emitting display device, a method of forming the light emitting layer may include a deposition method, a printing method, and the like. Among them, the printing method is useful as a method of forming the light emitting layer in a manufacturing process of a large-sized organic light emitting display device. However, in the case of using the printing method, the surface of the light emitting layer may not be formed to be flat, but may be formed in a convex dome shape or a concave lens shape. For example, a light emitting layer may be formed separately pixel by pixel in an organic light emitting display device, and the light emitting layer may be formed in a dome shape or a concave lens shape due to a difference in surface tension between a pixel defining layer for configuring (or partitioning) the light emitting layer in different pixels, and a material for forming the light emitting layer as described above.

As such, in the case where a light emitting layer is formed in the convex dome shape or the concave lens shape, a current density may be different at different locations within a pixel and thus there may be a problem with stability of an element during driving for a long time. Accordingly, when an organic light emitting display device is manufactured, the light emitting layer should be flatly formed, and particularly, when the light emitting layer of the organic light emitting display device is formed by a printing method, a technology to flatly form the surface of the light emitting layer should be used.

### SUMMARY

Aspects of embodiments of the present invention provide an organic light emitting display device capable of improving a structure of an auxiliary light emitting layer disposed below a light emitting layer to form flatly the surface of the light emitting layer of the organic light emitting display device.

Aspects of embodiments of the present invention also provide an organic light emitting display device of which the surface of a light emitting layer is flatly formed.

Aspects of embodiments of the present invention further provide a method of manufacturing an organic light emitting display device so that the surface of a light emitting layer is flatly formed.

Aspects of embodiments of the present invention further provide a method of manufacturing an organic light emitting display device so that the surface of a light emitting layer is flatly formed when the light emitting layer of the organic light emitting display device is formed by a printing method.

An exemplary embodiment of the present invention provides an organic light emitting display device, including: a substrate; a first electrode on the substrate; an auxiliary light emitting layer on the first electrode and having a pattern including a plurality of sub-patterns spaced apart from each other; a light emitting layer on the auxiliary light emitting layer; and a second electrode on the light emitting layer.

A pixel defining layer may be at edge sides of the first electrode to configure the first electrode for a pixel unit and define a pixel area, and corresponding ones of the sub-patterns may be at a position corresponding to the pixel area of the auxiliary light emitting layer.

The auxiliary light emitting layer having the pattern including the plurality of sub-patterns spaced apart from each other may be a hole transport layer.

A hole injection layer may be between the hole transport layer and the first electrode.

The auxiliary light emitting layer having the pattern including the plurality of sub-patterns spaced apart from each other may be a hole injection layer.

A hole transport layer may be on the hole injection layer.

The hole transport layer may have substantially the same pattern as the pattern on the hole injection layer.

Each sub-pattern of the plurality of sub-patterns may include a slit, a cylinder, a prism, a cross column, a cone, a pyramid, a convex lens, or a concave lens.

A height of the pattern may be in the range of about 5 nm to 100 nm.

A distance between the sub-patterns may be in the range of about 3 μm to 30 μm.

A width of a bottom of each sub-pattern of the plurality of sub-patterns may be in the range of about 3 μm to 30 μm.

The pattern may include a plurality of slits in parallel to each other in one direction, and a height of the slits may be about 5 nm to 100 nm, a distance between the slits may be about 3 μm to 30 μm, and a width of each of the slits may be about 3 μm to 30 μm.

According to another embodiment of the present invention, a manufacturing method of an organic light emitting display device includes forming a first electrode on a substrate; forming an auxiliary light emitting layer having a pattern including a plurality of sub-patterns spaced apart from each other, on the first electrode; forming a light emitting layer on the auxiliary light emitting layer; and forming a second electrode on the light emitting layer.

The method may further include forming a pixel defining layer to configure the first electrode for a pixel unit to define a pixel area, the pixel defining layer being formed at edge sides of the first electrode after the forming of the first electrode. The pattern may be formed at a portion corresponding to the pixel area, in the forming of the auxiliary light emitting layer.

The forming the auxiliary light emitting layer may include applying a material for forming the auxiliary light emitting layer on the first electrode; and patterning the material for forming the auxiliary light emitting layer.

The material for forming the auxiliary light emitting layer may be a photopolymerizable material.

The material for forming the auxiliary light emitting layer may include at least one of a material for hole injection and a material for hole transport; a photosensitizer; and a photoinitiator.

The photosensitizer may include a transparent photosensitive resin.

The patterning the material for forming the auxiliary light emitting layer may include disposing a pattern mask over the material for forming the auxiliary light emitting layer on the first electrode; irradiating light through the pattern mask; and developing the light-irradiated material for forming the auxiliary light emitting layer.

In the forming the auxiliary light emitting layer, a hole injection layer having a pattern may be formed.

The method may further include forming a hole transport layer on the hole injection layer.

In the forming the auxiliary light emitting layer, a hole transport layer having a pattern may be formed.

The method may further include forming a hole injection layer on the first electrode before forming the hole transport layer.

In the forming the light emitting layer, a material for forming the light emitting layer may be printed.

The printing may be any one of inkjet printing and gravure printing.

In an organic light emitting display device according to an embodiment of the present invention, a light emitting layer disposed on an auxiliary light emitting layer may be flatly formed by forming a pattern on the auxiliary light emitting layer. According to an embodiment of the present invention, since a contact area between the auxiliary light emitting layer and the light emitting layer is increased by forming the pattern on the auxiliary light emitting layer, holes may be smoothly injected and transported into the light emitting layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating an organic light emitting display device in the related art, wherein a light emitting layer is formed in a convex dome shape.

FIG. 2 is a cross-sectional view schematically illustrating an organic light emitting display device having a flat light emitting layer according to an embodiment of the present invention.

FIG. 3 is a cross-sectional view schematically illustrating a structure of an organic light emitting display device according to an embodiment of the present invention.

FIG. 4 is a cross-sectional view schematically illustrating a structure of an organic light emitting display device according to another embodiment of the present invention.

FIG. 5 is a perspective view separately illustrating a structure of an auxiliary light emitting layer having slit-shaped patterns.

FIG. 6 is a cross-sectional view schematically illustrating a structure of an organic light emitting display device according to an embodiment of the present invention.

FIGS. 7A to 7H are diagrams schematically illustrating a manufacturing process of an organic light emitting display device according to an exemplary embodiment of the present invention.

### DETAILED DESCRIPTION

Hereinafter, aspects of the present invention will be described in detail with reference to embodiments illustrated in the drawings. The scope of the present invention is not limited to drawings or embodiments to be described below. The drawings only select and illustrate examples suitable for describing the present invention among various embodiments.

Respective components and shapes thereof were schematically drawn or exaggeratedly drawn in the accompanying drawings for ease of understanding, and some components which would be used in a real product may not be illustrated and are omitted from the drawings. Therefore, the drawings may be analyzed in order to help understand the present invention. Meanwhile, like reference numerals designate like components playing the same role in the drawings.

Further, it will be understood that when a layer or an element is described as being “on” another layer or element, it may be directly disposed on another layer or element, or an intervening layer or element may also be present.

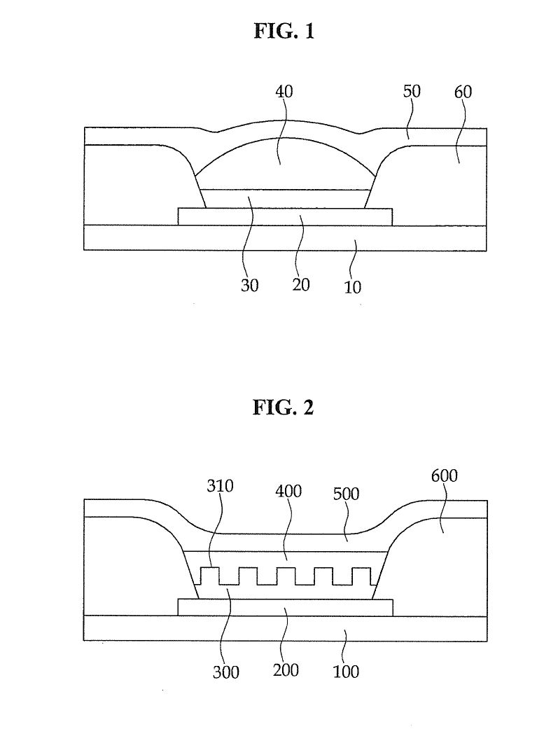

According to an embodiment, an organic light emitting display device includes a substrate 10, a first electrode 20 formed on the substrate, a light emitting layer 40 formed on the first electrode, and a second electrode 50 formed on the light emitting layer 40, as illustrated in FIG. 1. Further, an auxiliary light emitting layer 30 may be disposed between the first electrode 20 and the light emitting layer 40, and a hole injection layer and a hole transport layer may be included in the auxiliary light emitting layer. Further, the first electrode 20 may be configured (or partitioned) by the pixel defining layer 60 for a pixel unit, and a pixel area may be defined.

In an organic light emitting display device according to an embodiment of the present invention, representative methods for forming the light emitting layer 40 include a deposition method and a printing method. For example, in order to form a light emitting layer of a large-sized organic light emitting display device, a printing method has recently been attempted. However, in the case of using a printing method, as illustrated in FIG. 1, the light emitting layer 40 may be formed in a dome shape in some cases. One of the reasons may be a difference in a surface tension between the pixel defining layer 60 for configuring (or partitioning) the light emitting layer 40 for a pixel unit and to define a pixel area, and a material for forming the light emitting layer. That is, due to the difference in the surface tension between the pixel defining layer 60 and the material for forming the light emitting layer, the material for forming the light emitting layer is distributed in a dome shape while forming the light emitting layer and thus the light emitting layer 40 is formed in a dome shape. As illustrated in FIG. 1, in the case where the surface of the light emitting layer 40 is not flat, but convex or concave, there may be a problem with a light emitting characteristic and there may be a problem in that a current density in a pixel is different at different locations within the pixel.

In embodiments of the present invention, as illustrated in FIG. 2, a pattern 310 is formed on the auxiliary light emitting layer 300 disposed between the light emitting layer 400 and the first electrode 20. The material for forming the light emitting layer is uniformly (or substantially uniformly) spread by the pattern and thus the surface of the light emitting layer has a flat surface. As illustrated in FIG. 2, in the case where the pattern is formed on the auxiliary light emitting layer 300 disposed below the light emitting layer 400, the material for forming the light emitting layer may be uniformly (or substantially uniformly) dispersed by a capillary phenomenon. Further, a contact area between the auxiliary light emitting layer and the light emitting layer is increased by forming the pattern on the auxiliary light emitting layer and thus the holes may be smoothly injected and transported into the light emitting layer.

For example, as illustrated in FIG. 2, an organic light emitting display device according to an embodiment of the present invention includes a substrate 100, a first electrode 200 formed on the substrate 100, an auxiliary light emitting layer 300 formed on the first electrode 200, a light emitting layer 400 formed on the auxiliary light emitting layer 300, and a second electrode 500 formed on the light emitting layer 400. A pattern 310 including a plurality of sub-patterns spaced apart from each other is formed on the auxiliary light emitting layer 300.

As illustrated in FIG. 2, a pixel defining layer 600 is disposed at edge sides of the first electrode 200 and thus configures (or partitions) the first electrode into a pixel unit and defines pixel areas. The pattern 310 formed on the auxiliary light emitting layer 300 is formed at a portion corresponding to the pixel area among regions of the auxiliary light emitting layer. As such, the material for forming the light emitting layer may be uniformly (or substantially uniformly) dispersed in the pixel area by forming the pattern 310 in the pixel area and thus the light emitting layer 400 may be flatly formed.

In another embodiment, the plurality of sub-patterns may be formed in areas other than the pixel area as well as in the pixel area.

The auxiliary light emitting layer 300 may be a hole injection layer and may be a hole transport layer. Further, the auxiliary light emitting layer 300 may be a laminate of a hole injection layer and a hole transport layer.

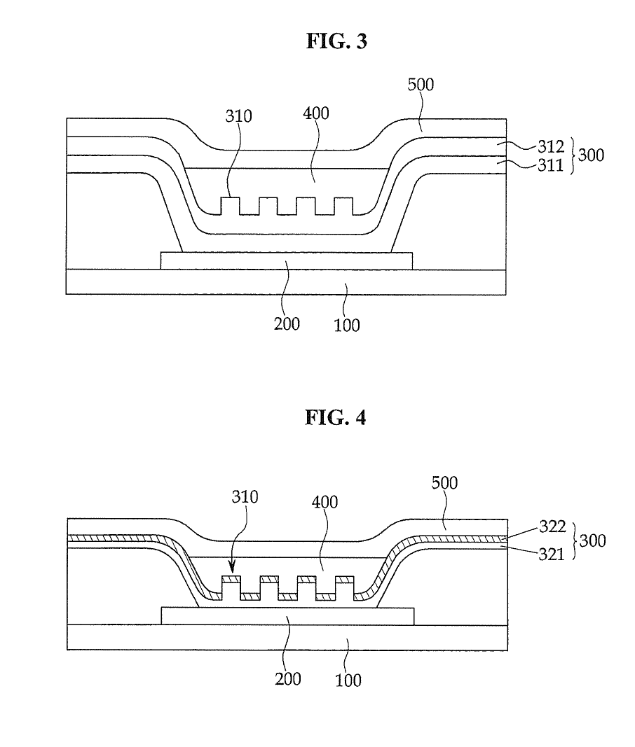

In FIG. 3, a case where the auxiliary light emitting layer 300 is formed as a laminate of hole injection layer 311 and hole transport layer 312 is illustrated. In FIG. 4, a case where the auxiliary light emitting layer 300 is formed as a laminate of hole injection layer 321 and hole transport layer 322, is illustrated.

For example, in FIG. 3, the auxiliary light emitting layer 300 with the plurality of sub-patterns spaced apart from each other is exemplified as a hole transport layer 312. That is, in the organic light emitting display device illustrated in FIG. 3, the plurality of sub-patterns is formed on the hole transport layer 312. Further, a hole injection layer 311 may be disposed between the hole transport layer 312 and the first electrode 200. Here, the hole transport layer 312 and the hole injection layer 311 form the auxiliary light emitting layer 300.

In another embodiment, only the hole transport layer 312 of FIG. 3 may form the auxiliary light emitting layer without the hole injection layer 311.

In FIG. 4, the auxiliary light emitting layer with the pattern including the plurality of sub-patterns spaced apart from each other is exemplified as a hole injection layer 321. That is, in the organic light emitting display device illustrated in FIG. 4, the plurality of sub-patterns is formed on the hole injection layer 321. Further, the hole transport layer 322 may be disposed on the hole injection layer 321. In such an embodiment, the hole transport layer 322 has substantially the same pattern as the pattern formed on the hole injection layer 321 (see FIG. 4). Here, the hole injection layer 321 and the hole transport layer 322 form the auxiliary light emitting layer 300.

In another embodiment, only the hole injection layer 321 of FIG. 4 may form the auxiliary light emitting layer without the hole transport layer 322.

Shapes of the sub-patterns of the pattern 310 are not particularly limited. Any shape may be applied to the pattern 310 without limit so long as nonuniformity may be applied to the surface of the auxiliary light emitting layer 300.

Examples of shapes of sub-patterns of a pattern 310 include a slit, a cylinder, a prism, a cross column, a cone, a pyramid, a convex lens, a concave lens, and the like. That is, the pattern 310 may have any one shape of a slit, a cylinder, a prism, a cross column, a cone, a pyramid, a convex lens, and a concave lens.

According to one embodiment, a height of the pattern 310 may be in the range of 5 nm to 100 nm, a distance between the sub-patterns of the pattern 310 may be in the range of 3 μm to 30 μm, and a width of the bottom of each sub-pattern of the pattern may be in the range of 3 μm to 30 μm.

The height of the pattern, the distance between sub-patterns of the pattern, and the width of each sub-pattern of the pattern may variously depend on a size of the pixel formed by the light emitting layer. As the size of the pixel is increased, the height, the distance, and the width of each sub-pattern of the pattern may be increased, and as the size of the pixel is decreased, the height of the pattern, the distance between sub-patterns of the pattern, and the width of each sub-pattern of the pattern may be decreased. The size of the pixel may depend on a size or a use of the organic light emitting display device.

According to an embodiment of the present invention, a pattern 310 may include a plurality of slits which are formed to be parallel to each other in one direction.

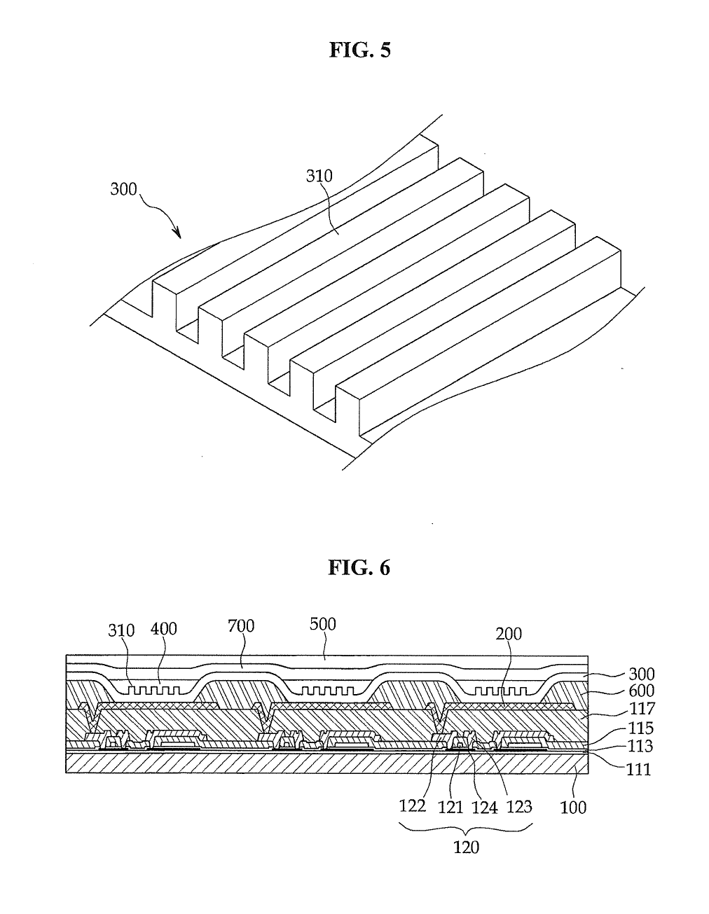

Hereinafter, an example in which the pattern 310 has a plurality of slits which are formed to be parallel to each other in one direction will be described. In this case, the slits may have a substantially same cross section as the pattern 310 illustrated in FIG. 3. In FIG. 5, an auxiliary light emitting layer 300 having a pattern 310 including slits is separately illustrated. In this case, a height of each slit may be 5 nm to 100 nm, a distance between the slits may be 3 μm to 30 μm, and a width of each slit may be 3 μm to 30 μm.

The height of the slits, the distance between slits, the width of each slit, and the number of slits may variously depend on a size of the pixel. The size of the pixel may depend on a size or a use of the organic light emitting display device.

FIG. 6 illustrates an organic light emitting display device according to another embodiment of the present invention in more detail. The organic light emitting display device illustrated in FIG. 6 includes a substrate 100, a first electrode 200 formed on the substrate 100, an auxiliary light emitting layer 300 formed on the first electrode 200, a light emitting layer 400 formed on the auxiliary light emitting layer 300, an electron layer 700 formed on the light emitting layer 400, and a second electrode 500 formed on the electron layer 700.

In the embodiment illustrated in FIG. 6, a top emission type organic light emitting display device in which light generated from the light emitting layer 400 is displayed in a direction of the second electrode 500, which is opposite to the substrate 100, is exemplified. Hereinafter, the top emission type organic light emitting display device will be described as an example as illustrated in FIG. 6.

First, the substrate 100 may be made of any glass or polymer plastic which is generally used in an organic light emitting display device. The substrate 100 may be transparent or may not be transparent. The substrate 100 may be selected and used according to the need of those skilled in the art.

The first electrode 200 is disposed on the substrate 100, and a plurality of thin film transistors 120 may be formed on the substrate 100 before the first electrode 200 is disposed on the substrate 100. Each thin film transistor 120 includes a gate electrode 121, a drain electrode 122, a source electrode 123, and a semiconductor layer 124 which are formed on the substrate 100. Further, a gate insulating layer 113 and an interlayer insulating layer 115 may also be provided in each thin film transistor 120. The structure of each thin film transistor 120 is not limited to the form illustrated in FIG. 6 and may be configured in another form. A buffer layer 111 made of silicon oxide, silicon nitride, or the like may be further included between the thin film transistor 120 and the first substrate 100.

The first electrode 200, the auxiliary light emitting layer 300, the light emitting layer 400, the electron layer 700, and the second electrode 500 are sequentially formed on the thin film transistors 120. The first electrode 200, the auxiliary light emitting layer 300, the light emitting layer 400, the electron layer 700, and the second electrode 500 may be integrally referred to as an “organic light emitting diode unit.”

In the embodiment illustrated in FIG. 6, the first electrode 200 corresponds to an anode as a pixel electrode which is electrically connected to the thin film transistor 120, and the second electrode 500 corresponds to a cathode as a common electrode.

The first electrode 200 is electrically connected with a corresponding thin film transistor 120 therebelow. In one embodiment, when a planarization layer 117 covering the thin film transistor 120 is provided, the first electrode 200 is disposed on the planarization layer 117. In such an embodiment, the first electrode 200 is electrically connected with the thin film transistor 120 through a contact hole provided in the planarization layer 117.

The first electrode 200 may be provided as a transparent electrode or a reflective electrode. In the case where the first electrode 200 is provided as a transparent electrode, the first substrate 100 may be made of ITO, IZO, ZnO or In₂O₃, and in the case where the first electrode 200 is provided as a reflective electrode, the first substrate 100 may include a reflective layer made of Ag, Mg, Al, Pt, Pd, Au, Ni, Nd, Ir, Cr, or their compounds and a layer made of ITO, IZO, ZnO or In2O3 thereon. In the case where the first electrode 200 is an anode, for example, ITO may be used as a material of the first electrode 200.

In the embodiment of FIG. 6, the first electrode 200 serves as an anode, and the second electrode 500 serves as a cathode, but polarities of the first electrode 200 and the second electrode 500 may be reversed.

A pixel defining layer (PDL) 600 is provided between the first electrodes 200. The pixel defining layer 600 may be made of a material having an insulation property, and may configure (or partition) the first electrode 200 for a pixel unit and define a pixel area. For example, the pixel defining layer 600 may be disposed at edge sides of the first electrode 200 to configure (or partition) the first electrode for a pixel unit and define pixel areas. The PDL 600 covers the edge of the first electrode 200.

According to an embodiment, the auxiliary light emitting layer 300 is formed on the first electrode 200. In one embodiment, the auxiliary light emitting layer 300 may be formed all over the first electrode 200 and the pixel defining layer 600. The auxiliary light emitting layer 300 may be a hole injection layer or a hole transport layer. A laminate of a hole injection layer and a hole transport layer may form the auxiliary light emitting layer 300. The auxiliary light emitting layer 300 according to an embodiment is described above.

The light emitting layer 400 is provided on the auxiliary light emitting layer 300. The light emitting layer 400 may be formed in a pixel area which is an opening on the first electrode 200 configured (or partitioned) by the pixel defining layer 600.

The electron layer 700 is formed on the light emitting layer 400. The electron layer 700 may be an electron injection layer or may be an electron transport layer. A laminate of an electron injection layer and an electron transport layer may form the electron layer 700.

The auxiliary light emitting (or emission) layer 300, the hole injection layer, the hole transport layer, the electron transport layer and the electron injection layer are collectively referred to as an organic layer. The organic layer may be made of a low-molecular organic material or a high-molecular organic material.

The low-molecular organic material may be applied to all of the hole injection layer, the hole transport layer, the light emitting (or emission) layer, the electron transport layer and the electron injection layer. The low-molecular organic material may be laminated in a single or complex structure, and the applicable organic material may include copper phthalocyanine (CuPc), N,N′-Di(naphthalene-1-yl)-N,N′-diphenyl-benzidine (NPB), tris-8-hydroxyquinoline aluminum (Alq3), and the like. The low-molecular organic materials may be formed by a method such as vacuum deposition using a mask and may be formed by a printing method such as inkjet or gravure printing.

The high-molecular organic material may be applied to, for example, a hole injection layer (HIL), a hole transport layer (HTL), a light emitting layer (EML), and the like. For example, the hole transport layer may be made of poly(3,4-ethylenedioxythiophene) (PEDOT), and the light emitting layer may be made of poly-phenylenevinylene (PPV)-based and polyfluorene-based high-molecular organic materials.

The second electrode 500 is formed on the electron layer 700. The second electrode 500 may be made of a material which is generally used in the art. The second electrode 500 may also be provided as a transparent electrode or a reflective electrode. When the second electrode 500 is provided as a transparent electrode, the second electrode 500 may include a layer made of Li, Ca, LiF/Ca, LiF/AI, Al, Mg or a compound thereof and a layer made of a material for forming a transparent electrode such as ITO, IZO, ZnO, or In2O3 thereon. When the second electrode 500 is provided as a reflective electrode, the second electrode 500 may be provided by depositing Li, Ca, LiF/Ca, LiF/AI, Al, Mg or their compounds. In the top emission type organic light emitting display device illustrated in FIG. 6, the second electrode 500 is manufactured as a transparent electrode. For example, the second electrode 500 may be formed by using LiF/Al.

A sealing material or an encapsulation layer may be further formed on the second electrode 500.

Another embodiment of the present invention provides a manufacturing method of an organic light emitting display device. For example, the manufacturing method may include forming a first electrode on a substrate, forming an auxiliary light emitting layer having a pattern including a plurality of sub-patterns spaced apart from each other on the first electrode, forming a light emitting layer on the auxiliary light emitting layer, and forming a second electrode on the light emitting layer.

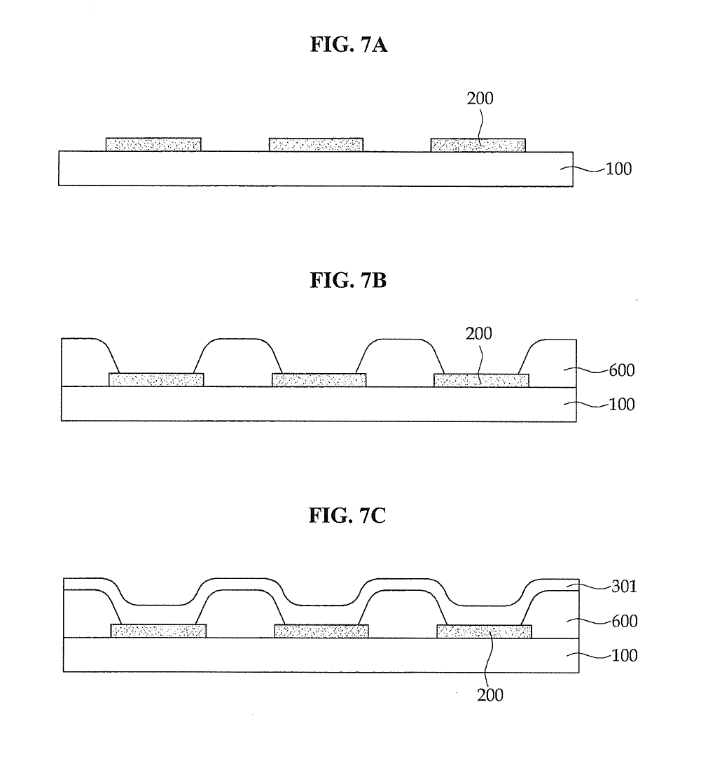

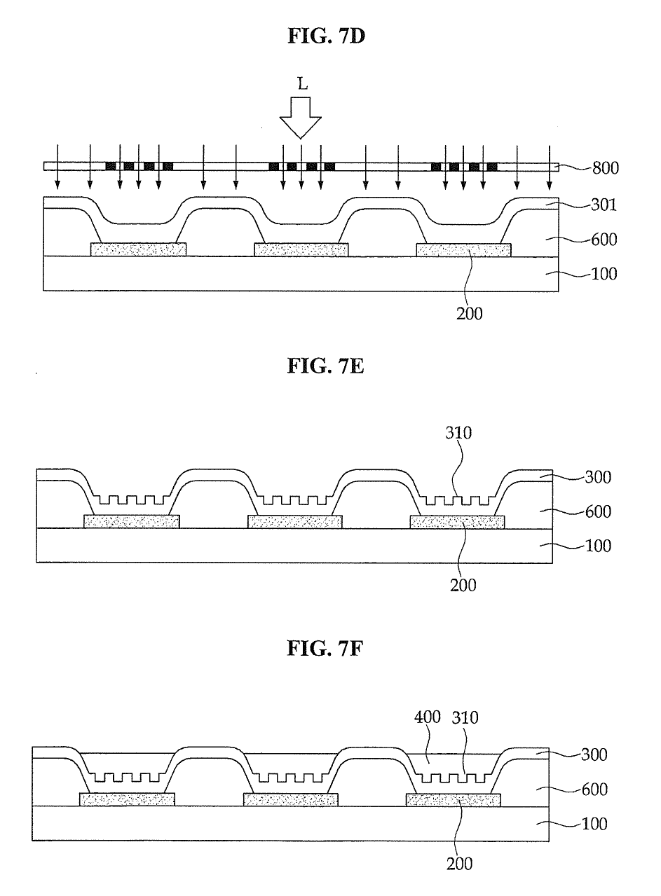

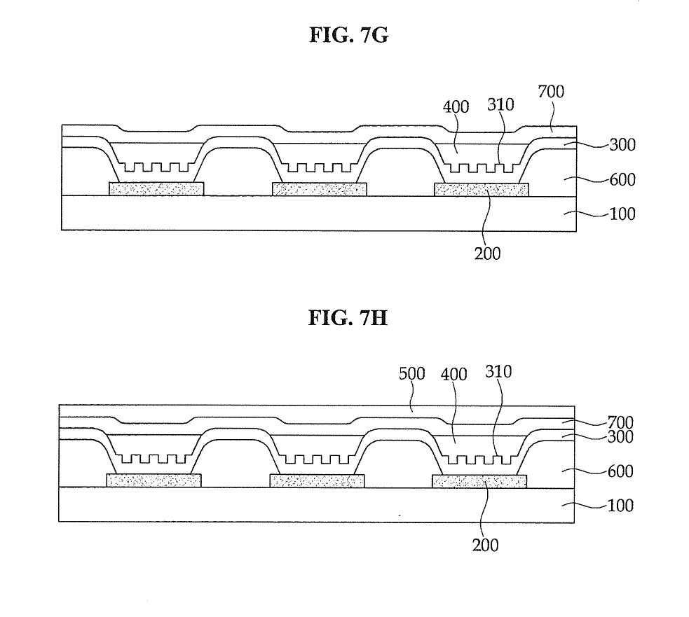

FIGS. 7A to 7F sequentially illustrate a manufacturing process of an organic light emitting display device according to an embodiment of the present invention.

In an embodiment, in order to manufacture the organic light emitting display device, first, the first electrode 200 is formed on the substrate 100 (see FIG. 7A).

The pixel defining layer 600 is formed between the first electrodes 200 (see FIG. 7B). That is, after the forming of the first electrode, a pixel defining layer 600 configuring (or partitioning) the first electrode for a pixel unit (e.g., pixel-by-pixel) and defining a pixel area is formed at edge sides of the first electrode. The opening formed by the pixel defining layer 600 becomes (or defines) a pixel area, and in the subsequent process of forming the auxiliary light emitting layer, the pattern provided in the auxiliary light emitting layer is formed at a portion corresponding to the pixel area.

The pixel defining layer 600 is made of a material having an insulation property, and configures (or partitions) the first electrode 200 for a pixel unit and defines a pixel area. The pixel defining layer 600 is formed at edge sides of the first electrode to define an area of the light emitting layer 400 and an area where the pattern provided on the auxiliary light emitting layer 300 is formed.

Next, a material 301 for forming the auxiliary light emitting layer 300 is applied all over the first electrode 200 and the pixel defining layer 600 (see FIG. 7C). Next, after a pattern mask 800 is disposed over the material 301 for forming the auxiliary light emitting layer and then light L is selectively irradiated with respect to the material 301 for forming the auxiliary light emitting layer 300 (see FIG. 7D) having a pattern 310 formed through developing (see FIG. 7E).

That is, according to an embodiment, the forming of the auxiliary light emitting layer 300 includes applying the material 301 for forming the auxiliary light emitting layer on the first electrode 200 (see FIG. 7C) and patterning the material 301 for forming the auxiliary light emitting layer (see FIG. 7D).

A photopolymerizable material may be used as the material 301 for forming the auxiliary light emitting layer. An example of a material for forming the auxiliary light emitting layer having a photopolymerizable property includes a material containing at least one of a material for hole injection and a material for hole transport, a photosensitizer, and a photoinitiator.

The material for hole injection may use any materials for forming the hole injection layer in the art. The material for hole injection may include, for example, CuPc, MTDATA, TDAPB, 1-NaphDATA, TPTE, and the like.

The material for hole transport may also use any materials for forming the hole transport layer in the art. The material for hole transport may include, for example, TPD, NPB, Spiro-TPD, DNIC, and the like.

An example of a photosensitizer includes a transparent photosensitive resin. In one embodiment, the transparent photosensitive resin is a resin which is polymerized by light irradiation.

The photosensitizer may include, for example, methacrylic acid, acrylic acid, crotonic acid, maleic acid, methyl methacylate, benzyl methacylate, 2-hydroxyethyl methacrylate, vinyl pyrrolidone, styrene, and the like.

The photoinitiator may use any materials which are generally used as a photoinitiator in the art. For example, acetophenone, acylphosphine, triazine, and the like may be used as the photoinitiator.

According to an embodiment, the patterning of the material 301 for forming the auxiliary light emitting layer (see FIG. 7D) includes disposing the pattern mask 800 over the material 301 for forming the auxiliary light emitting layer 300 disposed on the first electrode, irradiating light L through the pattern mask, and developing the material for forming the auxiliary light emitting layer.

In an embodiment, a light transmitting portion where the light is transmitted and a non-transmitting portion where the light is not transmitted are patterned and divided in the pattern mask 800. When the material 301 for forming the auxiliary light emitting layer is photopolymerized by irradiating the light L, since an irradiation amount of the light that reaches each portion of the material 301 for forming the auxiliary light emitting layer due to the pattern mask 800 varies, a difference in photopolymerization for each portion occurs. As a result, during the development, a difference in the degree of the development occurs to form the pattern 310 having a slit. The developing method may use a developing method which is generally used in the art. An etching may be performed after the developing. The etching may use a wet etching or dry etching method. The etching may also use an etching method which is generally used in the art.

According to an embodiment, in the forming of the auxiliary light emitting layer 300, a hole injection layer having the pattern 310 may be formed. In such an embodiment, the hole injection layer forms the auxiliary light emitting layer 300. The hole injection layer may singly form the auxiliary light emitting layer 300. The forming of the auxiliary light emitting layer 300 may further include forming a hole transport layer on the hole injection layer. A laminate of the hole injection layer and the hole transport layer may form the auxiliary light emitting layer 300 (see FIG. 4).

According to an embodiment, in the forming of the auxiliary light emitting layer 300, a hole transport layer having the pattern 310 may be formed. In such an embodiment, the hole transport layer forms the auxiliary light emitting layer 300. The hole transport layer may singly form the auxiliary light emitting layer 300. The forming of the auxiliary light emitting layer 300 may further include forming the hole injection layer on the first electrode before forming the hole transport layer. A laminate of the hole injection layer and the hole transport layer may form the auxiliary light emitting layer 300 (see FIG. 3).

The light emitting layer 400 may be formed on the auxiliary light emitting layer 300 with the pattern 310 (see FIG. 7F). In this case, the light emitting layer 400 is formed in an opening on the first electrodes 200 configured (or partitioned) by the pixel defining layer 600 for a pixel unit.

In the forming of the light emitting layer 400, a printing method may be used. That is, a material for forming the light emitting layer may be printed to form the light emitting layer. The printing may use any one of inkjet printing and gravure printing.

Recently, as a demand for a large-sized organic light emitting display device is increased, a printing method for forming the light emitting layer 400 has been attempted. However, in the case of using the printing method, the light emitting layer 400 may be formed in a dome shape due to a difference in a surface tension between the material for forming the light emitting layer and the pixel defining layer 600 in some cases. However, in an embodiment of the present invention, the material for forming the light emitting layer is uniformly (or substantially uniformly) spread by the pattern formed on the auxiliary light emitting layer 300 disposed between the light emitting layer 400 and the first electrode 200. As a result, the surface of the light emitting layer 400 may be flat (or more flat).

An electron layer 700 may be formed on the light emitting layer 400 and at a portion of the auxiliary light emitting layer 300 on which the light emitting layer 400 is not disposed (see FIG. 7G). The electron layer 700 may be an electron injection layer or an electron transport layer. A laminate of an electron injection layer and an electron transport layer may form the electron layer 700. In FIG. 7G, it is exemplified that the electron injection layer forms the electron layer 700. In some cases, the electron layer 700 may not be formed.

As such, in forming the electron layer 700 according to embodiments of the present invention, the second electrode 500 is formed on the electron layer 700 (see FIG. 7H). Accordingly, an organic light emitting display device as illustrated in FIG. 7H may be manufactured.

From the foregoing, it will be appreciated that embodiments of the present invention have been described herein for purposes of illustration, and that various modifications may be made without departing from the scope and spirit of the present invention. Accordingly, the embodiments disclosed herein are not intended to be limiting, with the true scope and spirit being indicated by the following claims and equivalents thereof.

What is claimed is:

1. An organic light emitting display device, comprising:
a substrate;
a first electrode on the substrate;
an auxiliary light emitting layer on the first electrode and having a pattern comprising a plurality of sub-patterns spaced apart from each other;
a light emitting layer on the auxiliary light emitting layer; and
a second electrode on the light emitting layer.

2. The organic light emitting display device of claim 1, wherein a pixel defining layer is at edge sides of the first electrode to configure the first electrode for a pixel unit and define a pixel area, and corresponding ones of the sub-patterns are at a position corresponding to the pixel area of the auxiliary light emitting layer.

3. The organic light emitting display device of claim 1, wherein the auxiliary light emitting layer having the pattern comprising the plurality of sub-patterns spaced apart from each other is a hole transport layer.

4. The organic light emitting display device of claim 3, wherein a hole injection layer is between the hole transport layer and the first electrode.

5. The organic light emitting display device of claim 1, wherein the auxiliary light emitting layer having the pattern comprising the plurality of sub-patterns spaced apart from each other is a hole injection layer.

6. The organic light emitting display device of claim 5, wherein a hole transport layer is on the hole injection layer.

7. The organic light emitting display device of claim 6, wherein the hole transport layer has substantially the same pattern as the pattern on the hole injection layer.

8. The organic light emitting display device of claim 1, wherein each sub-pattern of the plurality of sub-patterns comprises a slit, a cylinder, a prism, a cross column, a cone, a pyramid, a convex lens, or a concave lens.

9. The organic light emitting display device of claim 1, wherein a height of the pattern is in the range of about 5 nm to 100 nm.

10. The organic light emitting display device of claim 1, wherein a distance between the sub-patterns is in the range of about 3 μm to 30 μm.

11. The organic light emitting display device of claim 1, wherein a width of a bottom of each sub-pattern of the plurality of sub-patterns is in the range of about 3 μm to 30 μm.

12. The organic light emitting display device of claim 1, wherein the pattern comprises a plurality of slits in parallel to each other in one direction, and a height of the slits is about 5 nm to 100 nm, a distance between the slits is about 3 μm to 30 μm, and a width of each of the slits is about 3 μm to 30 μm.

13. A manufacturing method of an organic light emitting display device, comprising:
forming a first electrode on a substrate;
forming an auxiliary light emitting layer having a pattern comprising a plurality of sub-patterns spaced apart from each other, on the first electrode;
forming a light emitting layer on the auxiliary light emitting layer; and
forming a second electrode on the light emitting layer.

14. The manufacturing method of an organic light emitting display device of claim 13, further comprising:
forming a pixel defining layer to configure the first electrode for a pixel unit to define a pixel area, the pixel defining layer being formed at edge sides of the first electrode after the forming of the first electrode,
wherein the pattern is formed at a portion corresponding to the pixel area, in the forming of the auxiliary light emitting layer.

15. The manufacturing method of an organic light emitting display device of claim 13, wherein the forming the auxiliary light emitting layer comprises applying a material for forming the auxiliary light emitting layer on the first electrode; and patterning the material for forming the auxiliary light emitting layer.

16. The manufacturing method of an organic light emitting display device of claim 15, wherein the material for forming the auxiliary light emitting layer is a photopolymerizable material.

17. The manufacturing method of an organic light emitting display device of claim 15, wherein the material for forming the auxiliary light emitting layer comprises at least one of a material for hole injection and a material for hole transport; a photosensitizer; and a photoinitiator.

18. The manufacturing method of an organic light emitting display device of claim 17, wherein the photosensitizer comprises a transparent photosensitive resin.

19. The manufacturing method of an organic light emitting display device of claim 15, wherein the patterning the material for forming the auxiliary light emitting layer comprises disposing a pattern mask over the material for forming the auxiliary light emitting layer on the first electrode; irradiating light through the pattern mask; and developing the light-irradiated material for forming the auxiliary light emitting layer.

20. The manufacturing method of an organic light emitting display device of claim 13, wherein in the forming the auxiliary light emitting layer, a hole injection layer having a pattern is formed.

21. The manufacturing method of an organic light emitting display device of claim 20, further comprising:
forming a hole transport layer on the hole injection layer.

22. The manufacturing method of an organic light emitting display device of claim 13, wherein in the forming the auxiliary light emitting layer, a hole transport layer having a pattern is formed.

23. The manufacturing method of an organic light emitting display device of claim 22, further comprising:
forming a hole injection layer on the first electrode before forming the hole transport layer.

24. The manufacturing method of an organic light emitting display device of claim 13, wherein in the forming the light emitting layer, a material for forming the light emitting layer is printed.

25. The manufacturing method of an organic light emitting display device of claim 24, wherein the printing is any one of inkjet printing and gravure printing.
